(19) United States
(12) Patent Application Publication
(10) Pub. No.: US 2016/0020177 A1
(43) Pub. Date: Jan. 21, 2016

(54) RADIO FREQUENCY SHIELDING CAVITY PACKAGE

(71) Applicant: Ubotic Company Limited, Hong Kong (CN)

(72) Inventor: Ming-Wa TAM, Hong Kong (CN)

(21) Appl. No.: 14/737,982

(22) Filed: Jun. 12, 2015

Related U.S. Application Data
(60) Provisional application No. 62/011,762, filed on Jun. 13, 2014.

(51) Int. Cl. H01L 23/552; H01L 23/00; H01L 23/495; H01L 23/31; H01L 23/29; H01L 21/48; H01L 21/56

(52) U.S. Cl. CPC H01L 23/552; H01L 21/4828; H01L 21/4835; H01L 21/4821; H01L 24/85; H01L 24/83; H01L 24/92; H01L 21/565; H01L 23/3107; H01L 23/293; H01L 23/49503; H01L 23/49541; H01L 24/49; H01L 24/32; H01L 24/73; H01L 2224/73265; H01L 2224/32245; H01L 2224/48106; H01L 2224/48247; H01L 2224/92247

(57) ABSTRACT

A radio-frequency shielding cavity package is set forth along with a method of manufacturing thereof. According to one embodiment, the radio-frequency shielding cavity package comprises a metallic leadframe and plastic molded body. The leadframe has a plurality of contact pads extending from top to bottom surfaces thereof, at least one contact pad on the top surface being surrounded by metal for shielding the contact pad from external electric fields. A plated inner ring surrounds a die attach pad on the leadframe. The die attach pad receives a semiconductor die adapted to be wire bonded to the inner ring and plurality of contact pads. A plated outer ring defines a ground plane circumscribing the perimeter of the leadframe. A cap is connected to the ground plane for enclosing and protecting the wire bonded semiconductor device die and providing electrical grounding thereof.

### FIELD OF INVENTION

The present invention relates generally to integrated circuits, and more particularly to a radio-frequency shielding cavity package.

### BACKGROUND

Flat no-leads packages such as QFN (quad-flat no-leads) and DFN (dual-flat no-leads) are used to physically and electrically connect integrated circuits to printed circuit boards. Two types of flat no-leads packages are common: cavity (i.e. with a cavity designed into the package, containing air or nitrogen), and plastic-molded (i.e. with minimal air in the package). The cavity package is usually made up of three parts; a copper leadframe, plastic-molded body (open, and not sealed), and a cap or lid attached to the leadframe. An integrated circuit (IC) is mounted to a die attach pad within the cavity, with wire leads connecting the IC to the leadframe. The leadframe terminates in contacts on the bottom of the package for providing electrical interconnection with a printed circuit board.

Cavity packages are small and lightweight, with good thermal and electrical performance that makes them suitable for portable communication/consumer products. Applications include cellular phones, PDAs, wireless transmitters, RF front end, HD devices, microcontrollers, pre-amplifiers, servers, smart power suppliers, switches, DSPs, ASICs and wrist watches.

For high-speed applications, it is important that measures be taken to minimize cross-talk and ensure good grounding within the cavity package. Crosstalk originates when an electrical signal in a transmission line is coupled into an adjacent transmission line or circuit due to proximity effects. Crosstalk can cause timing errors in digital devices and can cause performance degradation in RF wireless devices. Adequate grounding is essential because ground serves as a reference datum for the overall circuit, and provides shielding as well as isolation.

### SUMMARY

A cavity package and method of fabrication are set forth wherein the contact pads used for high speed signaling are surrounded by a metal structure that is connected to ground (or reference ground/common). The metal structure shields the high speed signal contacts in a manner similar to a Faraday cage, which is an enclosure formed by conducting material that blocks external static and non-static electric fields by channeling electricity there through, for providing constant voltage on all sides of the enclosure such that no current flows through the enclosed space.

### BRIEF DESCRIPTION OF THE DRAWINGS

Features and advantages of the invention will be apparent from the detailed description which follows, taken in conjunction with the accompanying drawings, which together illustrate, by way of example, features of the invention; and, wherein:

FIG. 1 is a flowchart showing steps in a process for constructing a radio-frequency shielding cavity package, according to an exemplary embodiment.

FIG. 2 is a bottom view of a substrate for a radio-frequency shielding cavity package, fabricated according to the process of FIG. 1, having a metal leadframe and a dielectric molded body.

FIG. 3 is a top view of the substrate of FIG. 2.

FIGS. 4A-4C are bottom, top and cross-sectional views, respectively, of the substrate of FIGS. 2 and 3.

FIGS. 5A-5C are bottom, top and cross-sectional views, respectively, of the substrate of FIGS. 4A-4C after selective metal plating.

FIGS. 6A-6C are bottom, top and cross-sectional views, respectively, of the substrate of FIGS. 4A-4C after die attach and metal wire connection of the IC to contact pads of the metal leadframe.

FIGS. 7A-7C are bottom, top and cross-sectional views, respectively, of the radio-frequency shielding cavity package following attachment of a cap to protect the substrate.

FIG. 8 is a bottom view of a substrate for a radio-frequency shielding cavity package, fabricated according to the process of FIG. 1, having an alternative shape of contact pads.

FIG. 9 is a top view of the substrate of FIG. 8.

FIGS. 10A-10C are bottom, top and cross-sectional views, respectively, of the substrate of FIGS. 8 and 9.

FIGS. 11A-11C are top and cross-sectional views along lines 11B-11B and 11C-11C, respectively, showing an alternative design of contact pad with top and bottom interlocking features.

FIGS. 12A-12C are views of additional alternative designs of contact pad with top and bottom interlocking features, according to further embodiments.

FIGS. 13A-13C are top, bottom and elevation views, respectively, of a substrate for the alternative contact pad of FIG. 12B.

FIGS. 14A-14D are top, bottom, cross-sectional view through AA″ and cross-sectional view through BB″, respectively, of the substrate after applying and developing a photo-imageable resist.

FIGS. 14E and 14F are cross-sectional views through AA″ and BB″, respectively, of the substrate after etching to form a leadframe pattern.

FIGS. 15A-15D are top, bottom, cross-sectional view through AA″ and cross-sectional view through BB″, respectively, of the substrate after stripping away the etching resist and filling in the molded body.

FIGS. 16A-16D are bottom, top and cross-sectional view through AA″ and cross-sectional view through BB″, respectively, of the substrate after selective plating.

FIGS. 17A-17D are bottom, top and cross-sectional view through AA″ and cross-sectional view through BB″, respectively, of the substrate after etching away temporary tie bars.

FIGS. 18A-18C are bottom, top and cross-sectional views, respectively, of the substrate after die attach and metal wire connection of the IC to contact pads of the metal leadframe.

FIGS. 19A-19C are bottom, top and cross-sectional views, respectively, of the substrate following attachment of a cap to protect the substrate.

Reference will now be made to the exemplary embodiments illustrated, and specific language will be used herein to describe the same. It will nevertheless be understood that no limitation of the scope of the invention is thereby intended.

### DETAILED DESCRIPTION OF EXAMPLE EMBODIMENTS

Before the present invention is disclosed and described, it is to be understood that this invention is not limited to the particular structures, process steps, or materials disclosed herein, but is extended to equivalents thereof as would be recognized by those ordinarily skilled in the relevant arts. It should also be understood that terminology employed herein is used for the purpose of describing particular embodiments only and is not intended to be limiting.

As discussed below, in one embodiment the details of the method of fabricating the copper leadframe and plastic molded body are as set forth in U.S. Patent Application No. 61/870352, filed Aug. 27, 2013, and entitled PLASTIC CAVITY PACKAGE WITH A PRE-MOLDED SUBSTRATE, the contents of which are incorporated herein by reference.

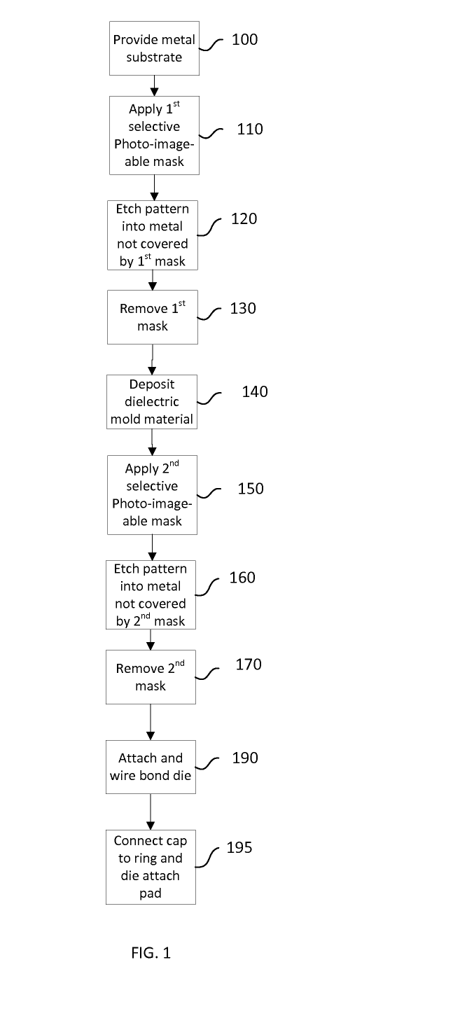

With reference to FIGS. 1 through 7A-7C, construction of a radio-frequency shielding cavity package is shown, according to an exemplary embodiment. It should be noted that whereas FIGS. 1 through 7A-7C set forth construction of a single cavity package, in practice a matrix comprising a plurality of cavity packages is fabricated so that multiple packages are fabricated simultaneously and then singulated into individual packages.

Construction of the cavity package begins at step 100 (FIG. 1) with fabrication of a metal (e.g. Cu or other metal alloy) substrate 200.

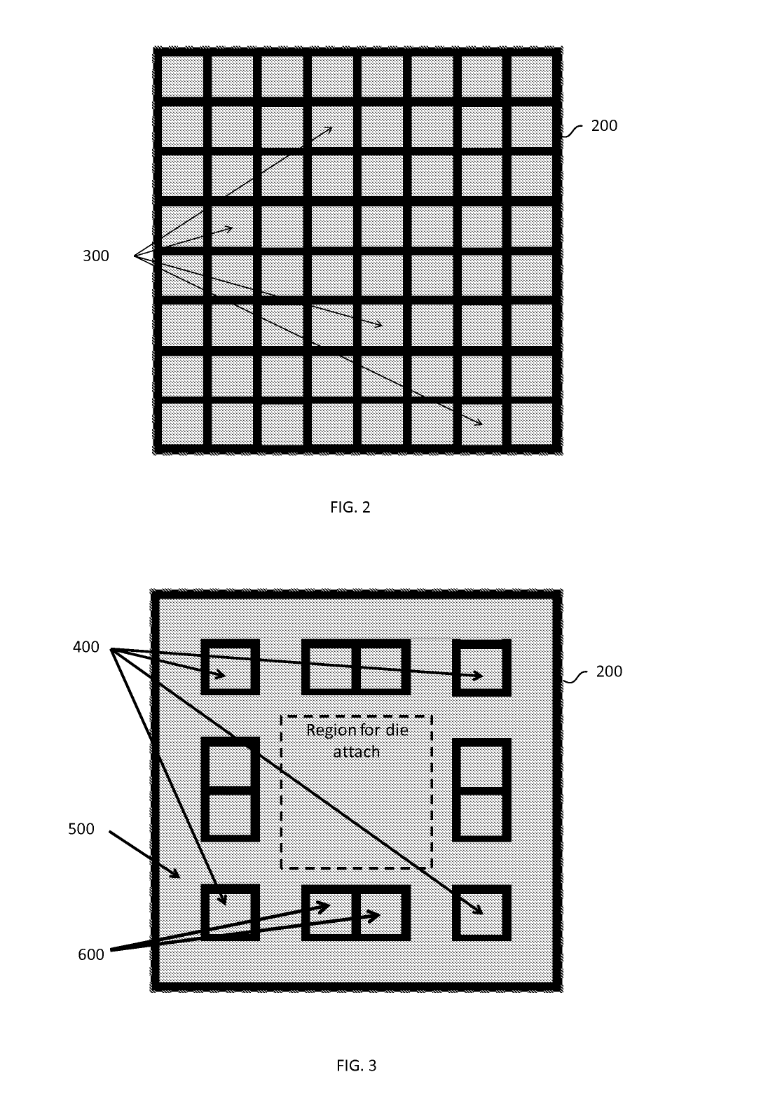

At step 110, a selective plating resist (e.g. Photo-image-able type) is applied to the top and bottom of substrate 200, to create a pattern that is etched at step 120 to define contacts pads 300 on the bottom for soldering on to a mother board after the cavity package has been fabricated, as shown in FIG. 2, and to define contacts pads 400, 600 and ground pad 500 on the top surface for connection to the IC, as shown in FIG. 3. The mask is then removed at step 130 and dielectric mold material is deposited at step 140.

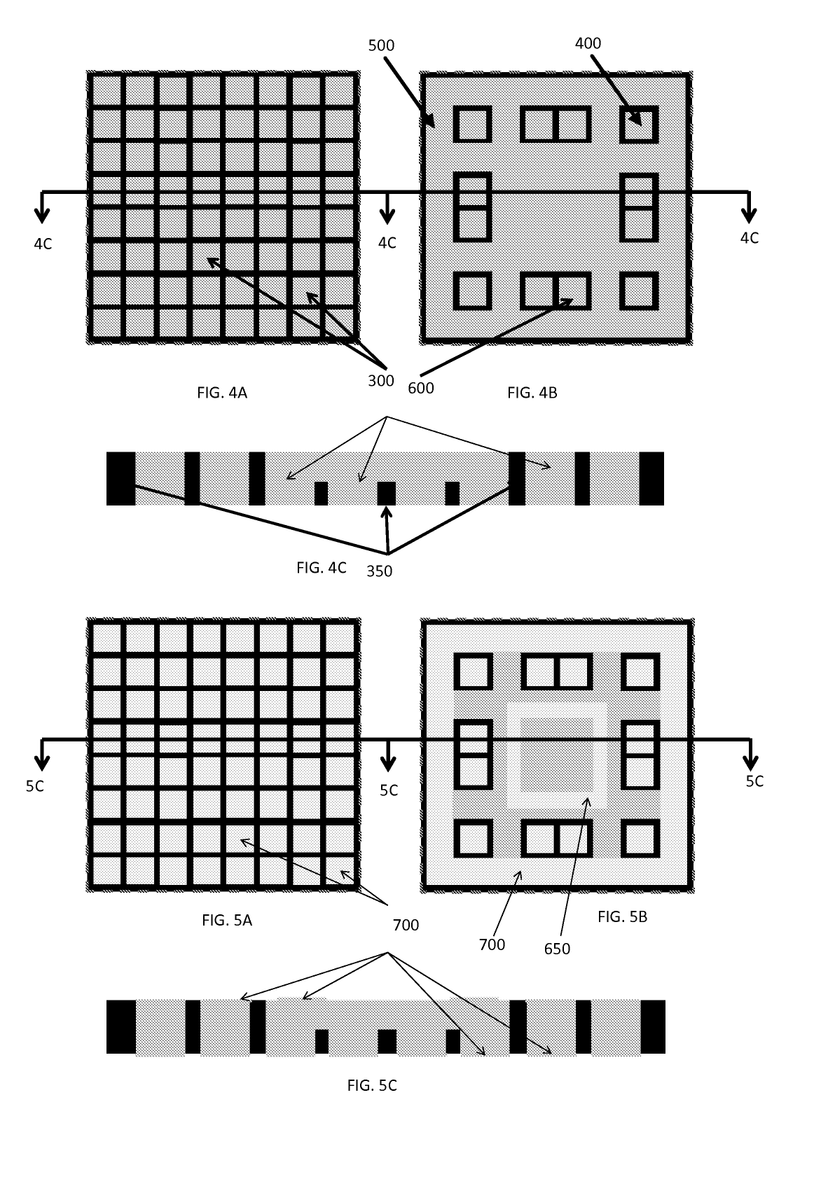

In one embodiment, the process of steps 110-140 can be as set forth in U.S. Patent Application No. 61/870352, filed Aug. 27, 2013, entitled PLASTIC CAVITY PACKAGE WITH A PRE-MOLDED SUBSTRATE, starting with selective plating (e.g. Ag, Ni/Au or Ni/Au/Pd, etc. . . ) via appropriate plating masks on the top and bottom sides of the metal substrate 200; followed by selective etching of the top and bottom sides of the metal substrate with appropriate etching masks such that, after etching the I/O contact pads are temporary held by partially etched tie bars (i.e. etched only from the top side of the substrate such that the temporary tie bars are not plated at the bottom). After etching has been completed, the dielectric mold 350 can be deposited onto the metal substrate to fill up all of the etched portions of the metal substrate. After molding, the temporary tie bars can be etched away from the bottom (i.e. they are not protected by the etch resistant plated metal), resulting in the molded metallic substrate shown in FIGS. 3 and 4A, 4B and 4C.

As shown in FIGS. 3 and 4A-4C, each of the contact pads 300 at the bottom is connected to an adjacent metal features on the top of the substrate (i.e. one-to-one connection between contact pads 400 and underlying contact pads 300; one-to-one connection between contact pads 600 and underlying contact pads 300; and one-to-many connection between ground pad 500 and underlying contact pads 300). The bottom contact pads 300 that are connected to top contact pads 400 and 600 are designed carry signals between the integrated circuit and the mother board, as discussed below, while the contact pads 300 that are connected to ground pad 500 provide a ground connection path from the integrated circuit to the mother board. The one-to-many connection between ground pad 500 and underlying contact pads 300minimizes the possibility of creating voids in the solder joint during surface mounting of the integrated circuit.

The contact pads 400 are isolated as a result of being surrounded by metal ground pad 500, and are used for carrying high-speed (frequency) signals. Contact pads 600 are provided for carrying the remaining I/O signals to and from the IC. The ground pad 500 electrically isolates the contacts 400 and shields the high speed signal contacts from radio frequency (RF) interference in a manner similar to a Faraday cage, by providing constant voltage on all sides of the high-speed contacts 400.

At steps 150-170, a second selective metal plating (e.g. Ag, Ni/Au, Ni/Au/Pd, etc.) is deposited using a selective plating resist according to the pattern shown in FIGS. 5A-5C, for creating an inner ring 650 that provides a common voltage area of the substrate surrounding a die attach pad, and an outer ring ground plane 700 circumscribing the perimeter of the substrate and deposited over the ground pad 500, for connecting a cap, as discussed further below.

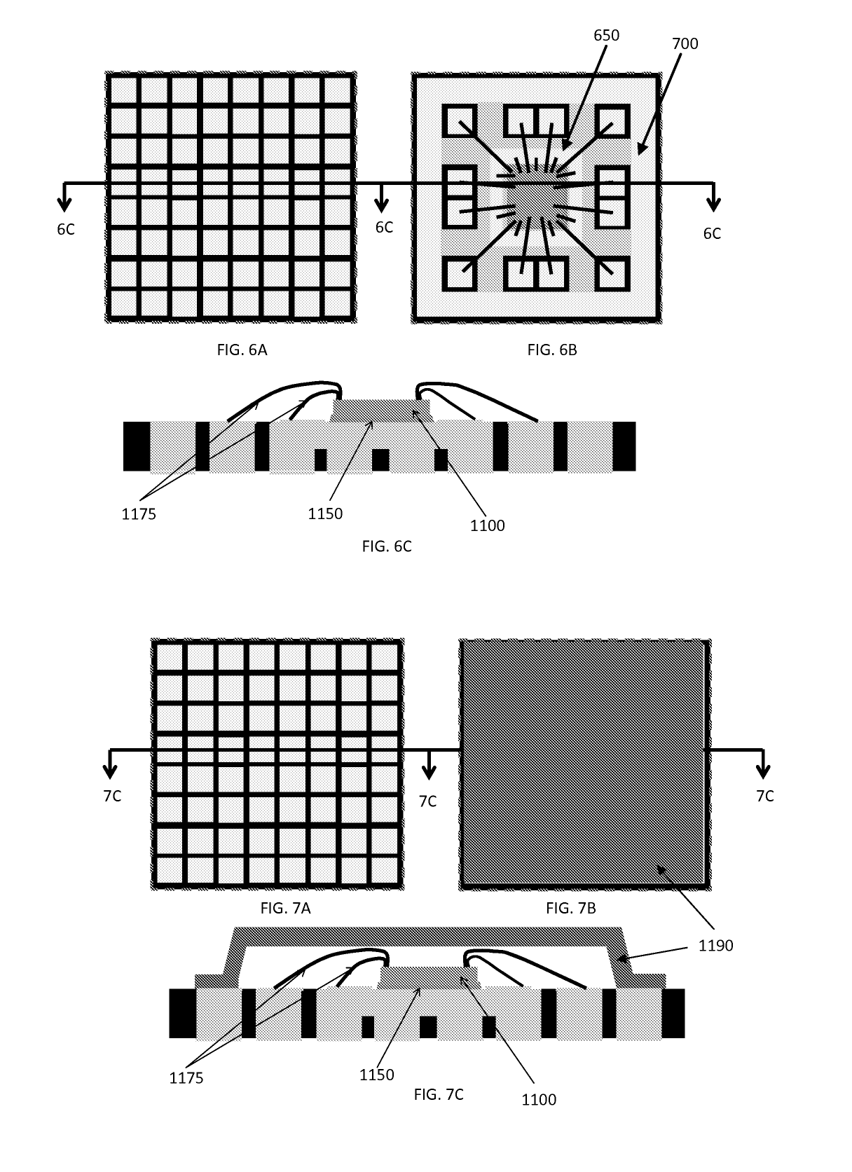

At step 190, the semiconductor device die 1100 (i.e. the IC) is placed in the region of the die attach pad (within the ring 650) and attached to the substrate via die attach epoxy 1150. The semiconductor device die 1100 is then wire bonded 1175 to the leadframe, as shown in FIGS. 6A-6C. In particular, wire bond connections are made to the inner ring 650 for grounding the semiconductor device die 1100, and to the contact pads 400 for carrying high-speed signals, as well as to the contact pads 600 for other I/O signals.

At step 195, a cap 11190 is attached and electrically connected to the outer ring ground plane 700 (e.g. by means of conductive epoxy or solder reflow) to protect the wire bonded device and permit electrical grounding, as shown in FIGS. 7A-7C.

As discussed above, in practice a matrix of cavity packages is fabricated (not shown) such that after the cap 1190 has been attached, the matrix is singulated (e.g. using saw singulation) to create packages, as shown in 7A-7C.

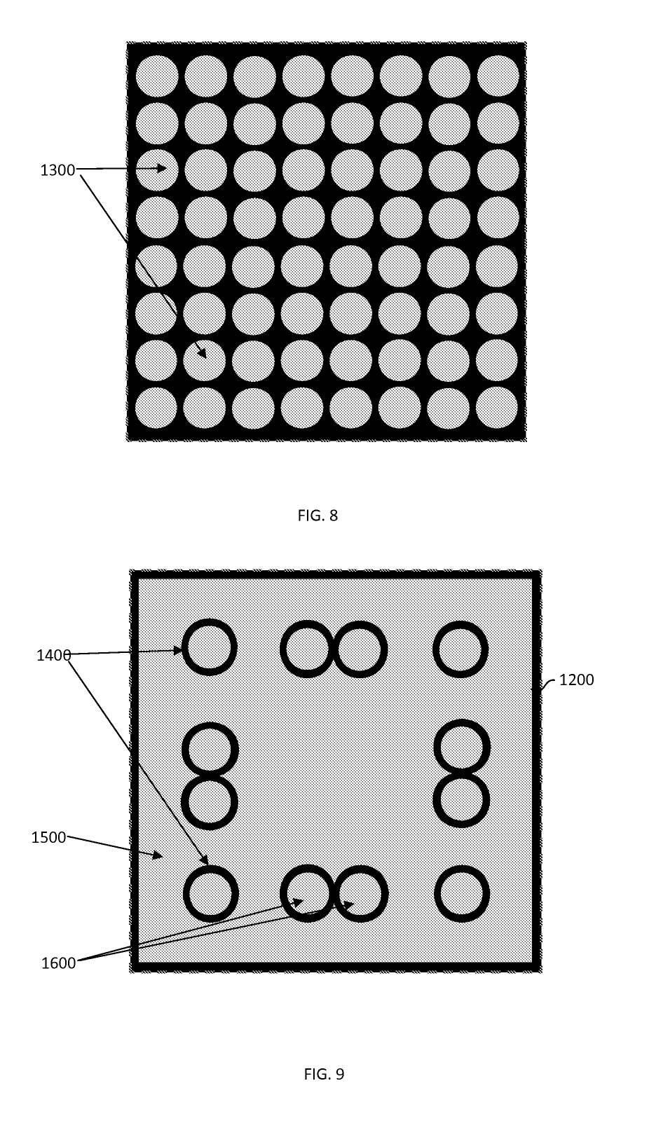

FIGS. 8 and 9 are bottom and top views of a substrate 1200 for a radio-frequency shielding cavity package, fabricated according to the process of FIG. 1, having an alternative shape of metal contacts 1300, 1400 and 1600 and dielectric molded body. The circular shaped contact pads 1300, 1400 and 1600 is less stress sensitive (e.g. to better withstand drop testing) than the square contact pads 300, 400 and 600 in the embodiment of FIGS. 1 and 2, because the circular design does not contain sharp corners, which is usually the stress concentrated region of the contact pads 300, 400 and 600.

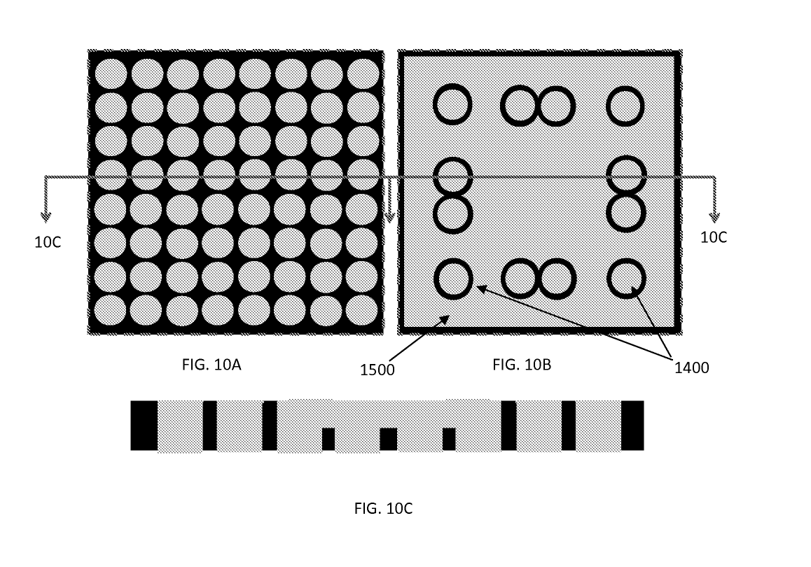

As shown in FIGS. 9 and 10A-10C, contact pads 1400 are isolated as a result of being surrounded by ground plane 1500, as in the embodiment of FIGS. 2-7, and are used for carrying high-speed (frequency) signals

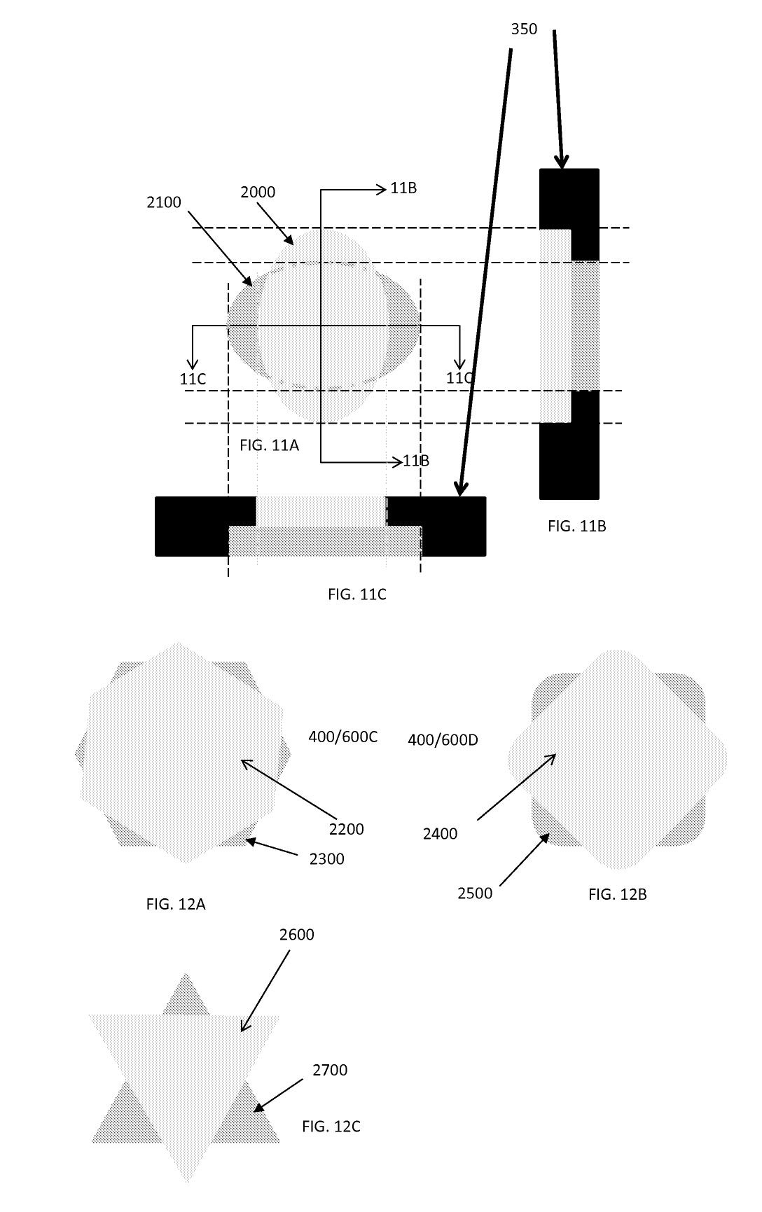

FIGS. 11A-11C show a further alternative design of contact pad with top and bottom interlocking features 2000 and 2100, which are preferably made of the same metallic material but are defined by different etching masks. The purpose of the interlocking features 2000 and 2100 is to prevent separation of the I/O contact pads from the mold body 350.

Likewise, FIGS. 12A-12C illustrate additional alternative designs of contact pads with interlocking features 2200 and 2300 (FIG. 12A); 2400 and 2500 (FIG. 12B) and 2600 and 2700 (FIG. 12C). Additional shapes are possible, provided that the etching masks are deposited so as to provide the afore-noted interlocking feature.

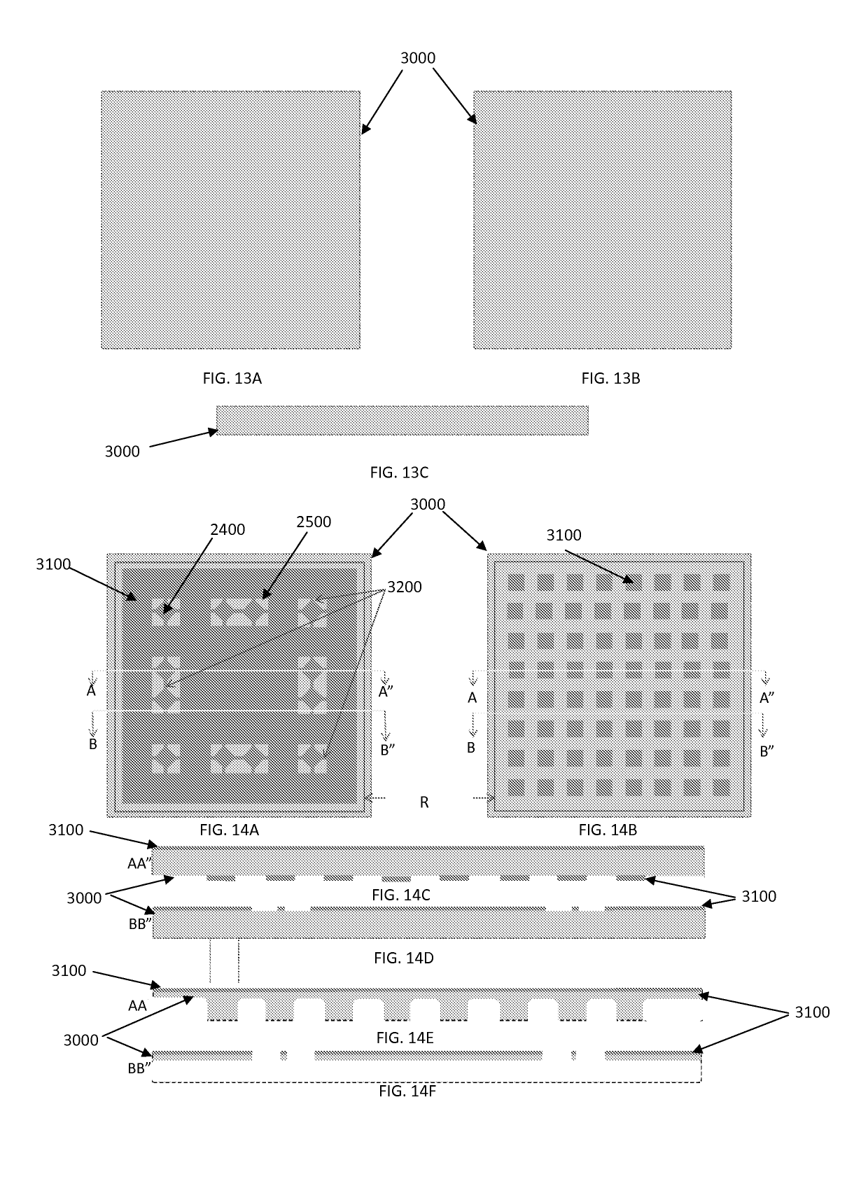

An exemplary process for fabricating the alternative design of contact pad with top and bottom interlocking features is set forth in FIGS. 13-19, with respect to the shape of contact pad depicted in FIG. 12B (i.e., offset diamond shape).

FIGS. 13A-13C are top, bottom and elevation views, respectively, of a copper substrate 3000 for the alternative contact pad of FIG. 12B.

FIGS. 14A-14D are top, bottom, cross-sectional view through AA″ and cross-sectional view through BB″, respectively, of the substrate 3000 after applying and developing a photo-imageable resist 3100, to define interlocking contact pad features 2400 and 2500, with temporary tie bars 3200. The rectangle identified by reference “R” does not form part of the design, but is included to show the boundaries of a single cavity package, bearing in mind that FIGS. 13 through 19 set forth construction of a single cavity package, whereas in practice a matrix comprising a plurality of cavity packages is fabricated so that multiple packages are fabricated simultaneously and then singulated into individual packages.

FIGS. 14 E and 14F are cross-sectional views through AA″ and BB″, respectively, of the substrate 3000 after etching to form a leadframe pattern. Etching is done from both sides of the substrate 3000 (top and bottom) such that the etching depth from each side is more than ½ of the thickness of the substrate.

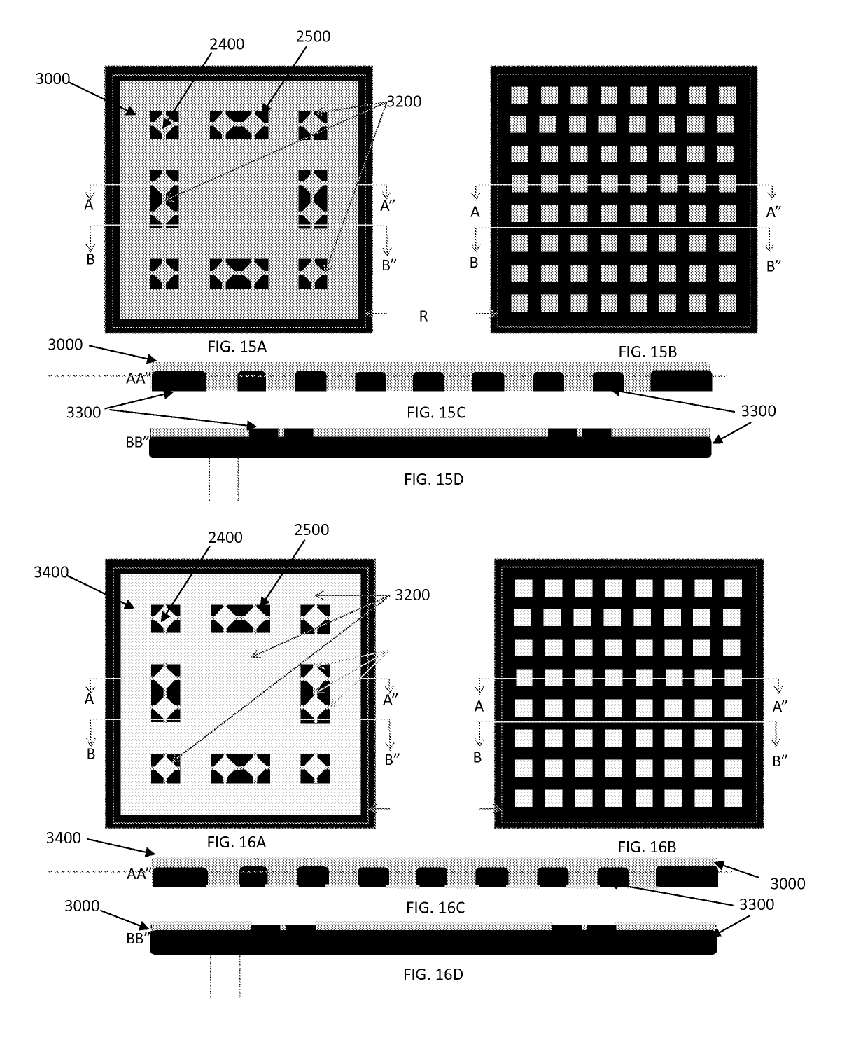

FIGS. 15A-15D are top, bottom, cross-sectional view through AA″ and cross-sectional view through BB″, respectively, of the substrate 3000 after stripping away the etching resist and filling in the etched away portions with molded body 3300.

FIGS. 16A-16D are bottom, top and cross-sectional view through AA″ and cross-sectional view through BB″, respectively, of the substrate 3000 after selective plating 3400 (e.g. Ni/Au, Ni/Au/Pd, Ag, etc.) onto both the top and bottom of the substrate. Note that the temporary tie bars 3200 are not plated.

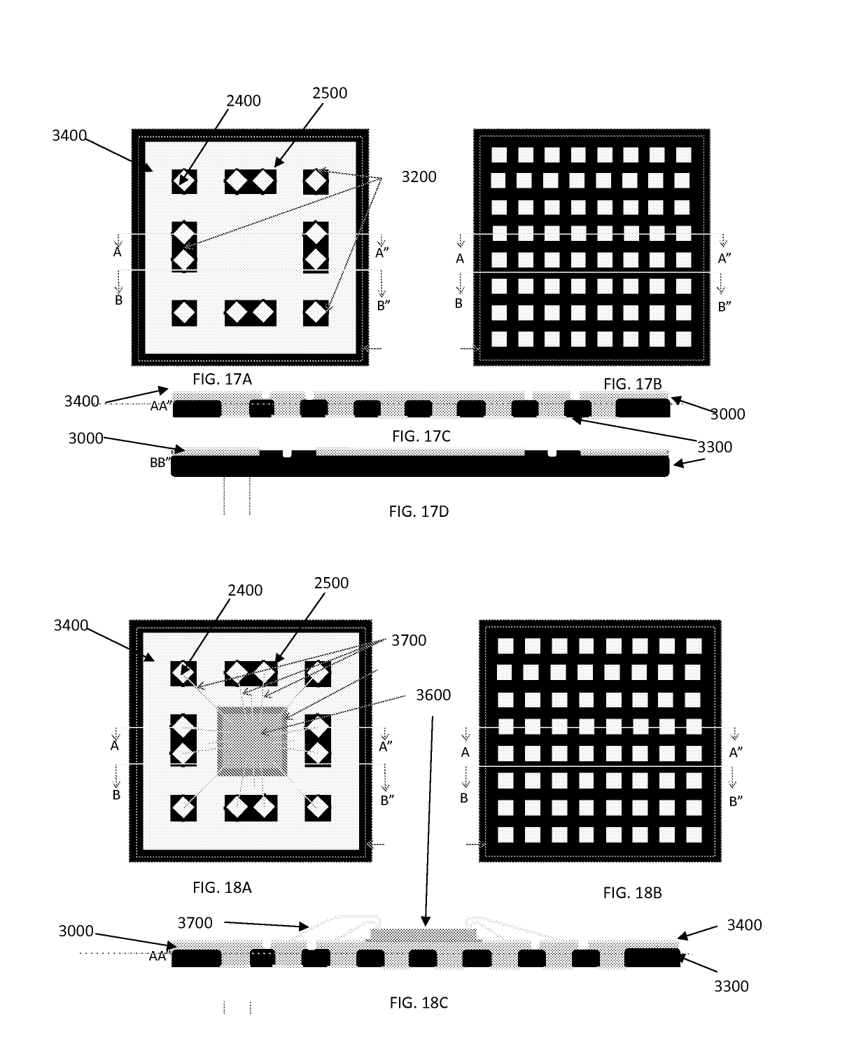

FIGS. 17A-17D are bottom, top and cross-sectional view through AA″ and cross-sectional view through BB″, respectively, of the substrate 3000 after etching away temporary tie bars, thereby isolating the metal interlocking features 2400 and 2500 from.

FIGS. 18A-18C are bottom, top and cross-sectional views, respectively, of the substrate 3000 after attaching the semiconductor (IC) die 3600 and connecting wires 3700 from the IC 3500 to the contact pads of the metal leadframe.

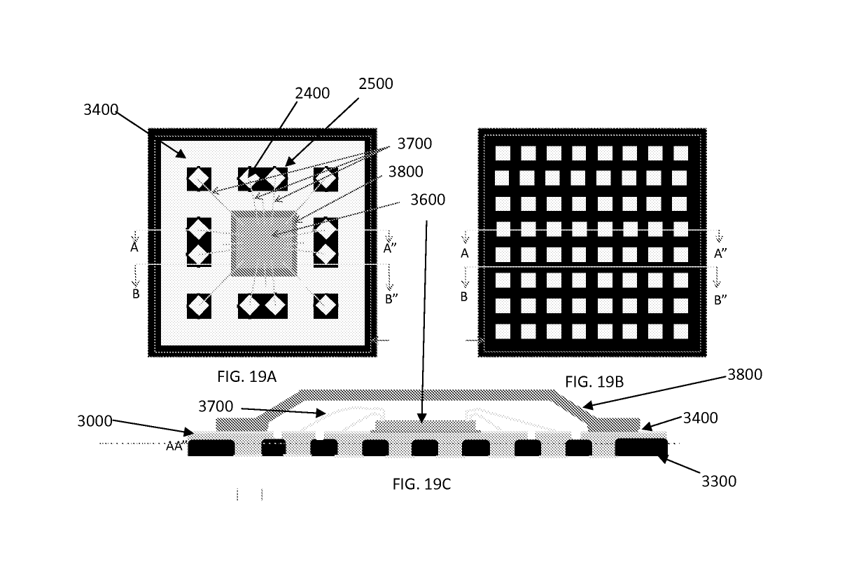

FIGS. 19A-19C are bottom, top and cross-sectional views, respectively, of the substrate 3000 after attaching a cap 3800 to protect the substrate. As discussed above, after the cap 3800 has been attached, the matrix is singulated (e.g. using saw singulation) into individual packages.

As shown in FIGS. 13 through 19, each of the contact pads at the bottom is connected to an adjacent metal features on the top of the substrate. The contact pads at each of the four corners of the substrate are designed carry high-speed signals between the integrated circuit and the mother board, and are isolated as a result of being surrounded by metal plating 3400, which electrically isolates the contact pads and shields the high speed signal contacts from radio frequency (RF) interference in a manner similar to a Faraday cage. While the forgoing exemplary embodiment is illustrative of the principles of the present invention, it will be apparent to those of ordinary skill in the art that numerous modifications in form, usage and details of implementation can be made without the exercise of inventive faculty, and without departing from the principles and concepts of the invention. Accordingly, it is not intended that the invention be limited, except as by the claims set forth below.

What is claimed is:

1. A method of manufacturing a radio-frequency shielding cavity package comprising:
i) applying a selective plating resist to a metallic substrate for defining a plurality of contact pads extending from top to bottom surfaces thereof, at least one contact pad on the top surface being surrounded by metal for shielding said at least one contact pad from external electric fields;
ii) selectively depositing metal plating using the selective plating resist;
iii) removing the selective metal plating resist;
iv) depositing dielectric mold material;
v) applying a selective etching resist to the substrate for defining an inner ring surrounding a die attach pad and an outer ring defining a ground plane, respectively;
vi) selectively etching portions of the substrate not covered by the selective etching resist;
vii) stripping away the selective etching resist;
viii) attaching a semiconductor device die to the die attach pad;
ix) wire bonding the semiconductor device to the inner ring and to the contact pads; and
x) attaching a cap to the ground plane for enclosing and protecting the wire bonded semiconductor device die and providing electrical grounding thereof.

2. The method of claim 1, wherein the cap is attached to the ring portion by means of epoxy.

3. The method of claim 1, wherein the cap is attached to the ring portion by means of solder reflow.

4. The method of claim 1, wherein said selective plating resist is applied so as to define interlocking features connected via tie bars that are removed during selective etching of the portions of the substrate not covered by selective etching resist, whereby the interlocking features resist separation of the contact pads from the dielectric mold material.

5. A radio-frequency shielding cavity package comprising:
a metallic leadframe and plastic molded body, said leadframe having a plurality of contact pads extending from top to bottom surfaces thereof, at least one contact pad on the top surface being surrounded by metal for shielding said at least one contact pad from external electric fields;
a plated inner ring surrounding a die attach pad on said leadframe, said die attach pad for receiving a semiconductor die adapted to be wire bonded to the inner ring for ground bonding, and plurality of plated contact pads;
a plated outer ring defining a ground plane circumscribing the perimeter of the leadframe; and
a cap connected to the ground plane for enclosing and protecting the wire bonded semiconductor device die and providing electrical grounding thereof.

6. The radio-frequency shielding cavity package of claim 5, wherein said at least one contact pad comprises at least two interlocking parts to prevent separation of the contact pad from the plastic molded body.

7. The radio-frequency shielding cavity package of claim 5, wherein said plurality of contacts are square shape.

8. The radio-frequency shielding cavity package of claim 5, wherein said plurality of contacts are circular.

9. The radio-frequency shielding cavity package of claim 6, wherein each of said interlocking features is oval shaped, and wherein the major axes thereof are orthogonal to each other.

10. The radio-frequency shielding cavity package of claim 6, wherein each interlocking feature is hexagonal and rotationally offset from the other interlocking feature so that each apex of one interlocking feature is located in the center of an adjacent side of the other interlocking feature.

11. The radio-frequency shielding cavity package of claim 6, wherein each interlocking feature is triangular and rotationally offset from the other interlocking feature so that each apex of one interlocking feature is located in the center of an adjacent side of the other interlocking feature.

12. The radio-frequency shielding cavity package of claim 6, wherein each interlocking feature is in the shape of a square with rounded corners and is rotationally offset from the other interlocking feature so that each corner of one interlocking feature is located in the center of an adjacent side of the other interlocking feature.
